(19) United States
(12) Patent Application Publication
(10) Pub. No.: US 2026/0280537 A1
(43) Pub. Date: Sep. 17, 2026

(54) HIGH-POWER LINEAR FLUX-PUMP SYSTEM

(71) Applicant: NORTHROP GRUMMAN SYSTEMS CORPORATION, FALLS CHURCH, VA (US)

(72) Inventors: HUGH PHILIPP, LINTHICUM, MD (US); HAITAO O. DAI, ELICOTT CITY, MD (US)

(21) Appl. No.: 19/038,151

(22) Filed: Jan. 27, 2025

(51) Int. Cl. H03K 3/78; H01F 6/00

(52) U.S. Cl. CPC H03K 3/78; H01F 6/006

(57) ABSTRACT

One example describes a linear flux-pump system. The system includes a trigger stage configured to generate a pulse train in response to an initialization current. The system also includes a current amplifier stage comprising a plurality of Josephson transmission line (JTL) stages configured to propagate MFQ pulses based on a clock signal in response to the pulse train. The system further includes a flux-pump stage configured to aggregate the MFQ pulses based on the clock signal to generate a DC output current.

### GOVERNMENT INTEREST

The invention was made under Government Contract. Therefore, the US Government has rights to the invention as specified in that contract.

### TECHNICAL FIELD

The present invention relates generally to superconducting circuits, and specifically to a high-power linear flux-pump system.

### BACKGROUND

Superconducting digital technology has provided computing and/or communications resources that benefit from unprecedented high speed, low power dissipation, and low operating temperature. Superconducting digital technology has been developed as an alternative to CMOS technology, and typically comprises superconductor based single flux quantum superconducting circuitry, utilizing superconducting Josephson junctions, and can exhibit typical power dissipation of less than 1 nW (nanowatt) per active device at a typical data rate of 20 Gb/s (gigabits/second) or greater, and can operate at temperatures of around 4 Kelvin or less. Certain superconducting circuits in which Josephson junctions are the active devices can require a DC current bias of the Josephson junctions. Typical superconducting systems can provide the DC bias current directly using a bias resistor network, which can result in spurious magnetic fields and heat resulting from high power dissipation. The power budget in such circuits can be dominated by static power consumption, which can be dissipated in the bias resistor network whether or not the active device is switching.

### SUMMARY

One example describes a linear flux-pump system. The system includes a trigger stage configured to generate a pulse train in response to an initialization current. The system also includes a current amplifier stage comprising a plurality of Josephson transmission line (JTL) stages configured to propagate multiple flux quanta (MFQ) pulses based on a clock signal in response to the pulse train. The system further includes a flux-pump stage configured to aggregate the MFQ pulses based on the clock signal to generate a DC output current.

Another example includes a method for generating a DC output current. The method includes providing an initialization current to a trigger stage of a linear flux-pump system to generate a pulse train. The linear flux-pump system further includes a current amplifier stage and a flux-pump stage. The method also includes providing a clock signal to the current amplifier stage and the flux-pump stage, the current amplifier stage being configured to generate MFQ pulses via JTL stages in response to the pulse train and the clock signal, and the flux-pump stage being configured to generate the DC output current in response to the MFQ pulses and the clock signal.

Another example includes a linear flux-pump system. The system includes a trigger stage configured to generate a pulse train in response to an initialization current. The system also includes a current amplifier stage. The current amplifier stage includes a first plurality of JTL stages configured to propagate first MFQ pulses based on a first phase of a clock signal in response to the pulse train, and a second plurality of JTL stages configured to propagate second MFQ pulses based on a second phase of the clock signal in response to the pulse train, the second phase being opposite the first phase. The system further includes a flux-pump stage. The flux-pump stage includes a first long Josephson junction comprising a first plurality of Josephson junctions inductively coupled to the clock signal to trigger in response to the first MFQ pulses and the first phase of the clock signal to generate a first portion of a DC output current, and a second long Josephson junction comprising a second plurality of Josephson junctions inductively coupled to the clock signal to trigger in response to the second MFQ pulses and the second phase of the clock signal to generate a second portion of the DC output current.

### BRIEF DESCRIPTION OF THE DRAWINGS

FIG. 1 illustrates an example of a linear flux-pump system.

FIG. 2 illustrates an example circuit diagram of a trigger stage.

FIG. 3 illustrates an example circuit diagram of a current amplifier stage.

FIG. 4 illustrates an example diagram of generating MFQ pulses.

FIG. 5 illustrates an example circuit diagram of a flux-pump stage.

FIG. 6 illustrates another example circuit diagram of a superconducting circuit system.

FIG. 7 illustrates an example of a method for generating a DC output current.

### DETAILED DESCRIPTION

The present invention relates generally to superconducting circuits, and specifically to a high-power linear flux-pump system. The high-power linear flux-pump system (hereinafter also referred to as “linear flux-pump system”) includes at least one multi-stage linear flux-pump. As described herein, the term “linear flux-pump” describes an arrangement of a plurality of Josephson transmission line (JTL) stages that are arranged in series between an input and a terminating end, and/or an arrangement of a sequence of Josephson junctions arranged as a long Josephson junction. For example, the terminating end can be arranged as a terminating resistor. As described herein, the high-power linear flux-pump system can be configured to deliver a greater current amplitude than conventional flux-pumps.

For example, a linear flux-pump system can include a trigger stage, a current amplifier stage, and a flux-pump stage, with each of the stages having different features. As an example, the trigger stage can be configured to generate a pulse train in response to an initialization current to begin operation of the linear flux-pump system. The initialization current can, for example, be provided as an inductively coupled current to initialize operation of the linear flux-pump system, such that a feedback current can be provided from the output of the linear flux-pump system to the trigger stage to maintain operation of the linear flux-pump system.

As another example, the current amplifier stage can include a sequence of JTL stages, with each of the JTL stages being arranged to include at least one Josephson junction that triggers in response to the clock signal to propagate a multiple flux quanta (MFQ) pulse through the sequence of JTL stages. The clock input can correspond to a secondary winding of a clock transformer (e.g., and a bias transformer) to inductively couple an AC clock signal to each JTL stage of the current amplifier stage, such that the AC clock signal provides a bias current to the respective JTL stage of the current amplifier stage. As yet another example, the flux-pump stage can include a long Josephson junction that is configured to trigger in response to an MFQ pulse and the clock signal to generate a long Josephson junction pulse. The long Josephson junction pulse can thus be provided from the linear flux-pump system as a DC output current (e.g., via an inductor).

As an example, the clock signal can be an AC clock signal (e.g., a quadrature clock signal, such as implemented in a reciprocal quantum logic (RQL) circuit). For example, the current amplifier stage can include first and second sets of JTL stages, and the flux-pump stage can include first and second long Josephson junctions. The first and second sets of JTL stages and the first and second long Josephson junctions can be arranged substantially similarly relative to each other, but can be biased on opposite phases of the AC clock signal. Therefore, the clock signal can be provided to a JTL stage of the first set of JTL stages of the current amplifier stage to trigger the Josephson junction(s) in response to the pulse train and the first phase of the clock signal, and can be provided to a JTL stage of the second set of JTL stages of the current amplifier stage one half period later to trigger the Josephson junction(s) in response to the pulse train and the second phase of the clock signal. Similarly, the clock signal can be provided to the first long Josephson junction of the flux-pump stage to trigger the first long Josephson junction in response to an MFQ pulse and the first phase of the clock signal to provide a first portion of the DC output current, and can be provided to the second long Josephson junction of the flux-pump stage to trigger the second long Josephson junction in response to an MFQ pulse and the second phase of the clock signal to provide a second portion of the DC output current.

The current amplifier stage can be fabricated such that the triggering of each Josephson junction can contribute a flux-pulse of greater than Φ₀. For example, the inductive couplings of the transformers to provide the clock signal to the JTL stages of the current amplifier stage can exhibit a high mutual inductance, such as to trigger the associated Josephson junctions to provide flux-pulses of greater than a single Φ₀ (e.g., 5Φ₀). As another example, the Josephson junction(s) of each of the JTL stages in the current amplifier stage can be progressively greater in size (e.g., critical current) with respect to the sequence of the JTL stages, thereby providing sequentially greater amplitude current pulses in response to triggering. Therefore, the triggering of the Josephson junctions of the flux-pump stage can provide high-current pulses with several Φ₀ of flux to the output of the linear flux-pump system at each cycle of the clock signal. Accordingly, the linear flux-pump system can provide sufficient voltage and current capability to operate as a DC current source for higher load demands relative to typical flux-pump systems that only provide a single Φ₀ per cycle of the clock signal.

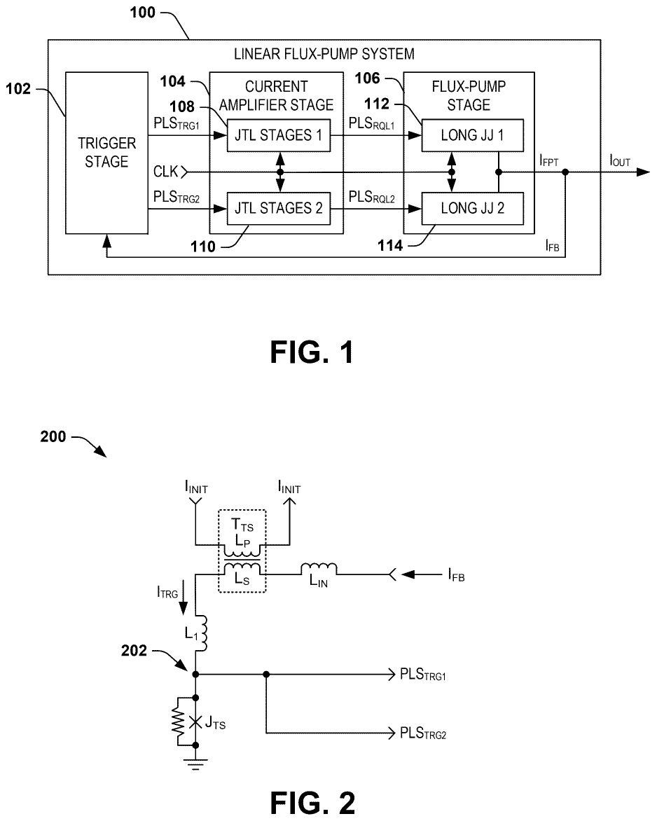

FIG. 1 illustrates an example of a linear flux-pump system 100. Similar to as described above in the example of FIG. 1, the linear flux-pump system 100 can be implemented in a superconducting circuit system for a variety of superconductor computing applications, such as memory or processing systems.

In the example of FIG. 1, the linear flux-pump system 100 includes a trigger stage 102, a current amplifier stage 104, and a flux-pump stage 106. As an example, the trigger stage 102 can be configured to generate a pair of pulse trains PLS_{TRG1} and PLS_{TRG2} in response to an initialization current (e.g., the current I_{INIT}, not shown in the example of FIG. 1). As an example, the pulse trains PLS_{TRG1} and PLS_{TRG2} can be generated by a Josephson junction that is triggered by the initialization current. The trigger stage 102 can receive a feedback current I_{FB} to sustain the operation of the linear flux-pump system 100 after the initialization current I_{INIT} ceases to the linear flux-pump system 100.

In the example of FIG. 1, the current amplifier stage 104 includes a first set of JTL stages 108 and a second set of JTL stages 110 that each include a sequential arrangement of JTL stages. As an example, the Josephson junction(s) of each JTL stage of the first set of JTL stages 108 triggers in response to the clock signal CLK and an input pulse. The clock input to each JTL stage of the sets of JTL stages 108 and 110 can correspond to a secondary winding of a clock transformer (e.g., a bias transformer) to inductively couple the clock signal CLK to each JTL stage of the sets of JTL stages 108 and 110. For example, the clock signal CLK can be configured to trigger the Josephson junction(s) of each JTL stage of the first set of JTL stages 108 on a first phase of the clock signal CLK, and to trigger the Josephson junction(s) of each JTL stage of the second set of JTL stages 110 on a second phase of the clock signal CLK. The first and second phases of the clock signal CLK can be opposite (e.g., 180° out-of-phase) of each other.

The input pulse to trigger each of the JTL stages of the first and second sets of JTL stages 108 and 110 can correspond to the respective pulse trains PLS_{TRG1} and PLS_{TRG2} and respective MFQ pulses PLS_{AMP1} and PLS_{AMP2}. For example, the input pulse to trigger the first JTL stage of the first set of JTL stages 108 can correspond to the pulse train PLS_{TRG1}, and the input pulse to trigger the remainder of the JTL stages of the first set of JTL stages 108 can correspond to the MFQ pulse PLS_{AMP1} that is sequentially generated through the remainder of the JTL stages of the first set of JTL stages 108. Therefore, the first set of JTL stages 108 can generate the MFQ pulse PLS_{AMP1} in response to the first phase of the clock signal CLK and the first pulse train PLS_{TRG1}. Similarly, the input pulse to trigger the first JTL stage of the second set of JTL stages 110 can correspond to the pulse train PLS_{TRG2}, and the input pulse to trigger the remainder of the JTL stages of the second set of JTL stages 110 can correspond to the MFQ pulse PLS_{AMP2} that is sequentially generated through the remainder of the JTL stages of the second set of JTL stages 108. Therefore, the second set of JTL stages 110 can generate the MFQ pulse PLS_{AMP2} in response to the second phase of the clock signal CLK and the second pulse train PLS_{TRG2}.

Also, in the example of FIG. 1, the flux-pump stage 106 includes a first long Josephson junction 112 and a second long Josephson junction 114. The first long Josephson junction 112 is configured to trigger in response to the first MFQ pulse PLS_{AMP1} provided from the first set of JTL stages 108 of the current amplifier stage 104 and the first phase of the clock signal CLK to generate a first long Josephson junction pulse. Similarly, the second long Josephson junction 114 is configured to trigger in response to the second MFQ pulse PLS_{AMP2} provided from the second set of JTL stages 110 of the current amplifier stage 104 and the second phase of the clock signal CLK to generate a second long Josephson junction pulse. In the example of FIG. 1, the long Josephson junction pulses can collectively form a flux-pump current I_{FP}, as described in greater detail herein. The flux-pump current I_{FP} is demonstrated as split into the feedback current I_{FB}, which is provided back to the trigger stage 102 to sustain operation of the linear flux-pump system 100, and the DC output current I_{OUT}.

While the example of FIG. 1 demonstrates that the flux-pump stage 106 includes long Josephson junctions (e.g., 112 and 114), a linear flux-pump system as described herein could instead implement a sequence of JTL stages in the flux-pump stage 106 instead of the long Josephson junctions 112 and 114. Implementation of one or the other of the alternative flux-pump stage 106 designs can be based on efficiency, spatial considerations, and/or other operational constraints.

FIG. 2 illustrates an example circuit diagram of a trigger stage 200. The trigger stage 200 can correspond to the trigger stage 106 or the trigger stage 102 in the respective example of FIG. 1. Therefore, reference is to be provided to the example of FIG. 1 in the following description of the example of FIG. 2.

The trigger stage 200 includes a coupling transformer T_{TS} that includes a primary L_{P} and a secondary L_{S}. The coupling transformer T_{TS} can correspond to any of a variety of inductive couplings that can be implemented in a superconducting circuit. The primary L_{P} is configured to conduct the initialization current I_{INIT} provided at an input of the trigger stage 200, such that the coupling transformer T_{TS} provides a trigger current I_{TRG} via the secondary L_{S} in response to the initialization current I_{INIT}. The trigger current I_{TRG} is provided through an inductor L₁ to a shunted Josephson junction J_{TS}. As described herein, the term “shunted Josephson junction” refers to a Josephson junction that is fabricated to have a parallel resistance, demonstrated in the circuit diagrams herein as a Josephson junction with a parallel resistor. The amplitude of the initialization current I_{INIT}, as well as the mutual inductance of the coupling transformer T_{TS}, can be sufficient to generate the trigger current I_{TRG} to have an amplitude that is sufficient to trigger the Josephson junction J_{TS}.

In response to triggering, the Josephson junction J_{TS} provides the first pulse train PLS_{TRG1} and the second pulse train PLS_{TRG2}. The example of FIG. 2 demonstrates that the two pulse trains PLS_{TRG1} and PLS_{TRG2} are provided from a common node 202 between the Josephson junction J_{TS} and the inductor L₁. However, any of a variety of pulse splitters can be implemented to provide both the first and second pulse trains PLS_{TRG1} and PLS_{TRG2} from the triggering of the Josephson junction J_{TS}. The first and second pulse trains PLS_{TRG1} and PLS_{TRG2} are thus provided to the current amplifier stage (e.g., to the sets of JTL stages 108 and 110 of the current amplifier stage 104) to generate the respective MFQ pulses PLS_{AMP1} and PLS_{AMP2}.

In addition, in the example of FIG. 2, the secondary L_{S} of the coupling transformer T_{TS} is coupled to another input to the trigger stage 200 via an input inductor LIN. In the example of FIG. 2, the input receives the feedback current I_{FB}, such as provided from the flux-pump current I_{FP} provided from the flux-pump stage (e.g., the flux-pump stage 110 or the flux-pump stage 106 in the respective example of FIG. 1). As described above, the initialization current I_{INIT} can be provided as a pulse or can be provided for a short period of time to initialize operation of the linear flux-pump system 100. Upon operation of the linear flux-pump system 100, the flux-pump current I_{FP}, and thus the feedback current I_{FB}, can be provided from the respective flux-pump stage. Therefore, the feedback current I_{FB} can be provided as feedback to the trigger stage 200 before cessation of the initialization current I_{INIT}, thereby sustaining operation of the linear flux-pump system 100.

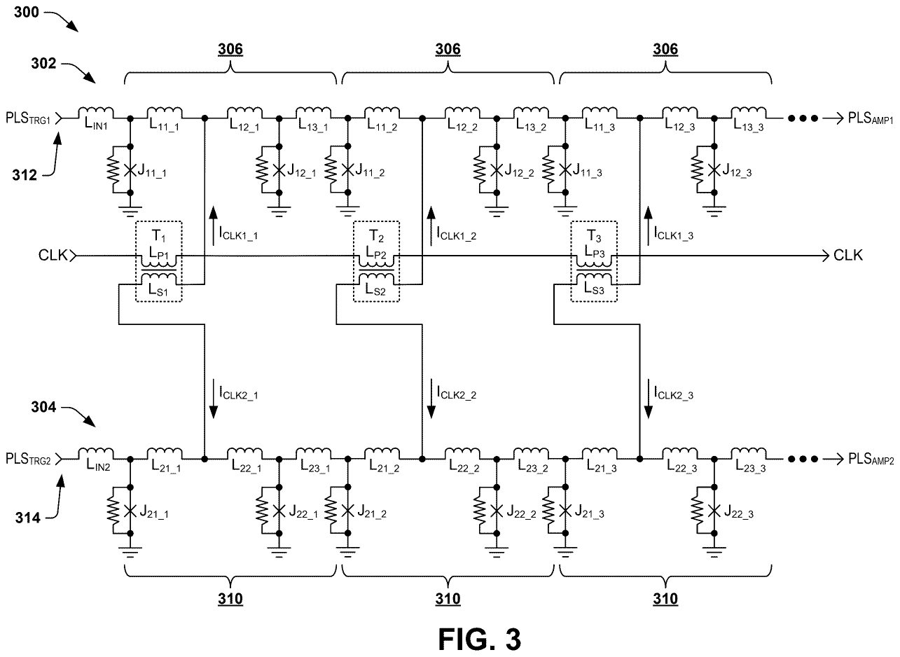

FIG. 3 illustrates an example circuit diagram of a current amplifier stage 300. The current amplifier stage 300 can correspond to the current amplifier stage 104 in the linear flux-pump system 100. Therefore, reference is to be made to the example of FIG. 1 in the following description of the example of FIG. 3.

The current amplifier stage 300 includes a first set of JTL stages 302 and a second set of JTL stages 304. Each of the first and second sets of JTL stages 302 and 304 are arranged approximately identically. The first set of JTL stages 302 includes an input inductor L_{IN1} and includes a plurality of individual JTL stages 306. Each of the JTL stages 306 includes a first inductor L_{11_X}, a second inductor L_{12_X}, and a third inductor L_{13_X}. In the example of FIG. 3, the designation “X” is an index corresponding to the number of the JTL stage to a total quantity of N stages. Therefore, the first inductors number L_{11_1} through L_{11_N}, the second inductors number L_{12_1} through L_{12_N}, and the third inductors number L_{13_1} through L_{13_N}. Each of the JTL stages 306 also includes a first Josephson junction J_{11_X} and a second Josephson junction J_{12_X}. In the example of FIG. 3, the Josephson junctions J_{11_X} and J_{12_X} are demonstrated as shunted Josephson junctions and therefore include a parallel resistor.

Each of the JTL stages 306 also includes a clock input, demonstrated in the example of FIG. 3 as a first polarity of a secondary winding L_{SX} of a transformer T_{X}. The primary winding L_{PX} of each of the transformers T_{X} is provided the clock signal CLK, which can be a sinusoidal clock signal (e.g., an in-phase or quadrature-phase component of an RQL clock). The first and second Josephson junctions J_{11_X} and J_{12_X} are therefore biased by a bias current I_{CLK1_X} that is provided via the secondary winding L_{SX} during a first phase of the clock signal CLK.

Similarly, the second set of JTL stages 304 includes an input inductor L_{IN2} and includes a plurality of JTL stages 310. Each of the JTL stages 310 includes a first inductor L_{21_X}, a second inductor L_{22_X}, and a third inductor L_{23_X}. Therefore, the first inductors number L_{21_1} through L_{21_N}, the second inductors number L_{22_1} through L_{22_N}, and the third inductors number L_{23_1} through L_{23_N}. Each of the JTL stages 310 also includes a first Josephson junction J_{21_X} and a second Josephson junction J_{22_X}. In the example of FIG. 3, the Josephson junctions J_{21_X} and J_{22_X} are demonstrated as shunted Josephson junctions and therefore include a parallel resistor.

Each of the JTL stages 310 also includes a clock input, demonstrated in the example of FIG. 3 as a second polarity, opposite the first polarity, of the secondary winding L_{SX} of a transformer T_{X}. Therefore, each of the JTL stages 306 and 310 share a common clock input L_{SX} based on being provided the respective bias currents from the opposing polarities of the secondary winding L_{SX} of a transformer T_{X}, and thus opposite phases of the clock signal CLK. Separate clock inputs (e.g., separate transformers) can be provided to the respective JTL stages 306 and 310. The first and second Josephson junctions J_{21_X} and J_{22_X} are therefore biased by a bias current I_{CLK2_X} that is provided via the secondary winding L_{SX} during a second phase of the clock signal CLK opposite the first phase. Therefore, the bias current I_{CLK2_X} has an opposite polarity as the bias current I_{CLK1_X}.

The opposite polarity of bias currents I_{CLK1_X} and I_{CLK2_X} through the secondary L_{SX} can result in the accumulation of Φ₀ based on the push-pull direction of the bias currents I_{CLK1_X} and I_{CLK2_X} with respect to the first and second phases of the clock signal CLK. In other words, by arranging the inputs of the bias currents I_{CLK1_X} and I_{CLK2_X} to be electrically coupled to each other through the secondary L_{SX}, the inputs are arranged as floating nodes that can accumulate Φ₀ flux, as opposed to coupling transformers in which the secondary is coupled to ground. Therefore, the accumulation of Φ₀ flux can provide multiple Φ₀ through the sequential triggering of the Josephson junctions in the associated JTL stages 306 and 310.

In the example of FIG. 3, the first pulse train PLS_{TRG1} is provided to an input 312 of the first set of JTL stages 302. During the first phase of the clock signal CLK, the secondary winding L_{S1} of the first transformer T₁ provides the bias current I_{CLK1_1} to the first JTL stage 306. Accordingly, the first and second Josephson junctions J_{11_1} and J_{12_1} trigger in response to the first pulse train PLS_{TRG1} and the bias current I_{CLK1_1}. The triggering of the Josephson junctions J_{11_1} and J_{12_1} generates a pulse (e.g., multiple flux quanta (MFQ) pulse) that propagates through the inductor L_{13_1} to the next JTL stage 306. The pulse can thus continue to propagate along each JTL stage 306 in the sequence of the first set of JTL stages 302 in the same manner during the first phase of the clock signal CLK. The pulse that is generated from the last JTL stage 306 of the first set of JTL stages 302 is thus provided as the first MFQ pulse PLS_{AMP1}.

Similarly, in the example of FIG. 3, the second pulse train PLS_{TRG2} is provided to an input 314 of the second set of JTL stages 304. During the second phase of the clock signal CLK, the secondary winding L_{S1} of the first transformer T₁ provides the bias current I_{CLK2_1} to the first JTL stage 310. Accordingly, the first and second Josephson junctions J_{21_1} and J_{22_1} trigger in response to the second pulse train PLS_{TRG2} and the bias current I_{CLK2_1}. The triggering of the Josephson junctions J_{21_1} and J_{22_1} generates a pulse (e.g., SFQ pulse) that propagates through the inductor L_{23_1} to the next JTL stage 310. The pulse can thus continue to propagate along each JTL stage 310 in the sequence of the second set of JTL stages 304 in the same manner during the second phase of the clock signal CLK. The pulse that is generated from the last JTL stage 310 of the second set of JTL stages 304 is thus provided as the second MFQ pulse PLS_{AMP2}.

As described above, the current amplifier stage 300 can be fabricated such that the triggering of the Josephson junctions in each of the JTL stages 306 and 310 can contribute a flux-pulse of greater than Φ₀. For example, the inductive couplings of the transformers T_{X} to provide the clock signal CLK to the JTL stages 306 and 310 can exhibit a high mutual inductance, such as to trigger the associated Josephson junctions of the JTL stages 306 and 310 to provide flux-pulses of greater than a single Φ₀ (e.g., 5Φ₀). As another example, the Josephson junctions of each of the JTL stages 306 and 310 in the current amplifier stage 300 can be progressively greater in size with respect to the sequence of the JTL stages 306 and 310, thereby providing sequentially greater amplitude current pulses in response to triggering. For example, the secondary L_{SX} of each of the respective transformers T_{X} can have a successively decreasing inductance corresponding to the successively increasing size of the Josephson junctions to provide proper biasing. Therefore, in response to the greater amplitude pulses provided to the flux-pump stage 106, the triggering of the long Josephson junction of the flux-pump stage 106 can provide a greater amplitude of output current from the linear flux-pump system 100.

As an example, inductive coupling for a conventional flux-pump can have a mutual inductance of the associated transformer to provide sufficient bias to trigger Josephson junctions in a JTL stage to provide a flux of a single Φ₀ (e.g., per cycle of an associated clock signal). For example, the mutual inductance of the conventional inductive coupling can be approximately 1 pH. However, the transformers T_{X} in the current amplifier stage 300 can exhibit a much higher mutual inductance, resulting in a significantly greater number of Φ₀ per clock cycle. The greater number of Φ₀ per clock cycle can be sufficient to trigger Josephson junctions in one of the JTL stages 306 and 310 to provide a flux of multiple Φ₀ (e.g., per cycle of the clock signal CLK), such as based also on the amplitude of resistance of the associated shunting of the respective Josephson junctions. As an example, the transformers T_{X} can exhibit a mutual inductance multiplied by the bias current exceeds 4 pH*mA to provide a sufficient bias to trigger the Josephson junctions in one of the JTL stages 306 and 310 to provide a flux of multiple Φ₀. Accordingly, the triggering of the long Josephson junction of the flux-pump stage 106 can provide several Φ₀ of flux to the output of the linear flux-pump system 100 at each cycle of the clock signal CLK.

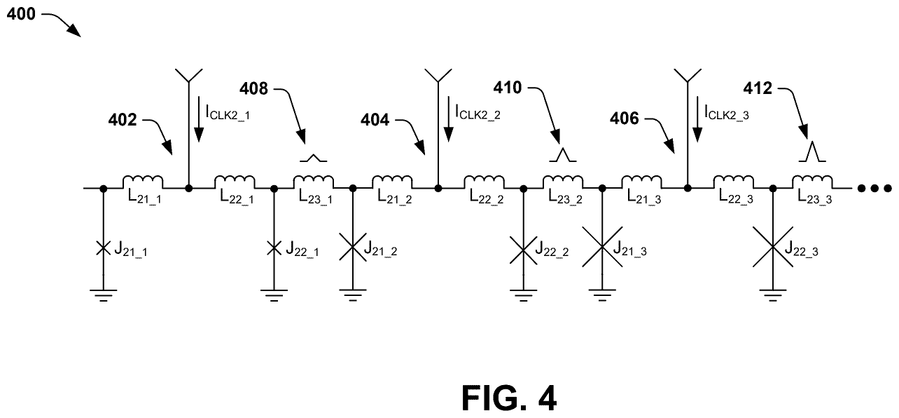

FIG. 4 illustrates an example diagram 400 of generating MFQ pulses. The diagram 400 demonstrates a portion of the set of JTL stages 304, and thus three JTL stages 310. As described above, the Josephson junctions of each of the JTL stages 306 and 310 in the current amplifier stage 300 can be progressively greater in size with respect to the sequence of the JTL stages 306 and 310, thereby providing sequentially greater amplitude pulses in response to triggering. The progressive increase in size of the Josephson junctions between the input of the current amplifier stage 300 (e.g., at which the pulse train PLS_{TRG} is provided) and the output of the current amplifier stage 300 (e.g., from which the MFQ pulse PLS_{AMP} is provided) is demonstrated diagrammatically in the example of FIG. 4.

In the example of FIG. 4, a first one of the JTL stages 402 is demonstrated diagrammatically as having a pair of Josephson junctions J_{21_1} and J_{22_1} of a nominal size, a second one of the JTL stages 404 is demonstrated diagrammatically as having a pair of Josephson junctions J_{21_2} and J_{22_2} of a size greater than the pair of Josephson junctions J_{21_1} and J_{22_1}, and a third one of the JTL stages 406 is demonstrated diagrammatically as having a pair of Josephson junctions J_{21_3} and J_{22_3} of a size greater than the pair of Josephson junctions J_{21_2} and J_{22_2}. The pictorial sizing of the Josephson junctions is provided in the example of FIG. 4 to represent a relative size increase of the Josephson junctions along the sequence of the JTL stages 402, 404, and 406, and is not intended to indicate actual size or relative scale of the Josephson junctions.

The progressive increase in size of the Josephson junctions can result in a progressive increase in the current amplitude of the pulses (e.g., MFQ pulses) that are generated by the triggering of the Josephson junctions in the respective JTL stages 306 and 310. In the example of FIG. 4, the progressively larger pulses are demonstrated at 408, 410, and 412. Particularly, the example of FIG. 4 diagrammatically demonstrates the first pulse 408 of a nominal size that is generated by the triggering of the pair of Josephson junctions J_{21_1} and J_{22_1}, the second pulse 410 that is generated by the triggering of the pair of Josephson junctions J_{21_2} and J_{22_2}, and the third pulse 412 that is generated by the triggering of the pair of Josephson junctions J_{21_3} and J_{22_3}. In the example of FIG. 4, the second pulse 410 is demonstrated as having a greater amplitude than the first pulse 408, and the third pulse 412 is demonstrated as having a greater amplitude than the second pulse 410. Similar to as described above, the pictorial sizing of the pulses 408, 410, and 412 is provided in the example of FIG. 4 to represent a relative size increase of the pulses generated by the Josephson junctions along the sequence of the JTL stages 402, 404, and 406, and is not intended to indicate actual size or relative scale of the pulses 408, 410, and 412.

Therefore, the diagram 400 demonstrates by diagram that the progressively larger Josephson junctions of the respective JTL stages 402, 404, and 406 provides for progressively greater amplitude pulses generated by the triggering of the Josephson junctions of the respective JTL stages 402, 404, and 406. The resulting MFQ pulses PLS_{AMP1} and PLS_{AMP2} can thus exhibit a greater amplitude of current relative to a typical flux-pump circuit. Therefore, as described herein, the triggering of the long Josephson junctions of the flux-pump stage 110 (e.g., the flux-pump stage 106) can provide for a higher amplitude current to provide the DC output current I_{OUT}.

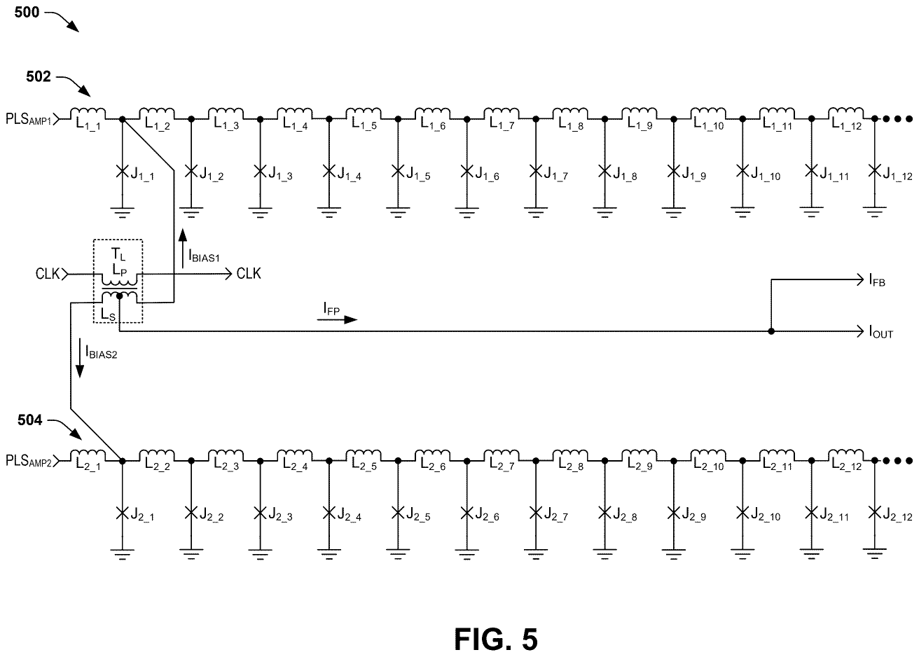

FIG. 5 illustrates an example circuit diagram of a flux-pump stage 500. The flux-pump stage 500 can correspond to flux-pump stage 110 or the flux-pump stage 106 in the example of FIG. 1, respectively. Therefore, reference is to be made to the example of FIG. 1 in the following description of the example of FIG. 5.

The flux-pump stage 500 includes a first long Josephson junction 502 and a second long Josephson junction 504. Each of the first and second long Josephson junctions 502 and 504 are arranged approximately identically, and each include a plurality of inductors and a plurality of Josephson junctions that are interleaved with respect to each other. The first long Josephson junction 502 includes inductors L_{1_X} and Josephson junctions J_{1_X}, wherein the designation “X” is an index corresponding to the number of the inductor and Josephson junction pair of the second long Josephson junction 504. Similarly, the second long Josephson junction 504 includes inductors L_{2_X} and Josephson junctions J_{2_X}, wherein the designation “X” is an index corresponding to the number of the inductor and Josephson junction pair of the second long Josephson junction 504. In the example of FIG. 5, the Josephson junctions J_{1_X} and J_{2_X} are demonstrated as unshunted Josephson junctions, and therefore do not include a parallel resistor.

The flux-pump stage 500 also includes a transformer T_{L}. A primary winding L_{P} of the transformers T_{L} is provided the clock signal CLK. The clock signal CLK thus inductively provides a first bias current I_{BIAS1} to the first long Josephson junction 502 (e.g., at the Josephson junction J_{1_1} between the inductors L_{1_1} and L_{1_2}) in a first phase of the clock signal CLK, and a second bias current I_{BIAS2} to the second long Josephson junction 504 (e.g., at the Josephson junction J_{2_1} between the inductors L_{2_1} and L_{2_2}) in a second phase of the clock signal CLK.

In the example of FIG. 5, the first long Josephson junction 502 is biased by the bias current I_{BIAS1} that is provided via the secondary winding L_{S} during the first phase of the clock signal CLK to collectively trigger the Josephson junctions J_{1_X} (e.g., in a sequence along the first long Josephson junction 502) in response to the first MFQ pulse PLS_{AMP1}. Similarly, the second long Josephson junction 504 is biased by the bias current I_{BIAS2} that is provided via the secondary winding L_{S} during the second phase of the clock signal CLK to collectively trigger the Josephson junctions J_{2_X} (e.g., in a sequence along the second long Josephson junction 504) in response to the second MFQ pulse PLS_{AMP2}.

The arrangement of the Josephson junctions J_{1_X} that form the first long Josephson junction 502 is such that the Josephson junctions J_{1_X} are biased by the bias current I_{BIAS1} such that a sufficient amplitude of the MFQ pulses PLS_{AMP1} can result in a chain reaction of triggering of the Josephson junctions J_{1_X} in respective sequential MFQ transitions. Similarly, the arrangement of the Josephson junctions J_{2_X} that form the second long Josephson junction 504 is such that the Josephson junctions J_{2_X} are biased by the bias current I_{BIAS2} such that a sufficient amplitude of the MFQ pulses PLS_{AMP2} can result in a chain reaction of triggering of the Josephson junctions J_{2_X} in respective sequential MFQ transitions.

Similar to as described above in the example of FIG. 3, the opposite polarity of the bias currents I_{BIAS1} and I_{BIAS2} through the secondary L_{S} can result in the accumulation of Φ₀ based on the push-pull direction of the bias currents I_{BIAS1} and I_{BIAS2} with respect to the first and second phases of the clock signal CLK. Therefore, the secondary winding LS acts as a floating nodes that can accumulate Φ₀ flux to provide multiple Φ₀ from the triggering of the Josephson junctions J_{1_X} and J_{2_X}. As a result, the first and second long Josephson junctions 502 and 504 can alternately trigger at the first and second phases of the clock signal CLK to each provide multiple Φ₀ of flux at each respective phase of the clock signal CLK that can accumulate at the secondary L_{S} of the transformer T_{L}.

In the example of FIG. 1, an output tap is located on the secondary winding LS. Thus, the current pulses provided from the first and second long Josephson junctions 502 and 504 that are accumulated at the secondary LS and stored as flux can provide the flux-pump current I_{FP} from the output tap. The flux-pump current I_{FP} can thus be split to provide the feedback current I_{FB} and the DC output current I_{OUT}. As described above, the feedback current I_{FB} can be provided to the trigger stage 102 to sustain the operation of the linear flux-pump system 100. The DC output current I_{OUT} can thus be provided as a current source to a load (e.g., the device 102). Based on the multiple Φ₀ of flux that can be provided by the linear flux-pump system 100 at each cycle of the clock signal CLK, as described herein, the linear flux-pump system 100 can provide sufficient voltage and current to satisfy operational requirements of a variety of different loads.

While the linear flux-pump system described herein is configured to provide greater than a single Φ₀ of flux at each cycle of the clock signal CLK, certain applications may require greater operational margins of voltage and/or current. To provide such greater margins of voltage and/or current, the linear flux-pump system described herein can be further cascaded by implementing multiple stages of linear flux-pump systems.

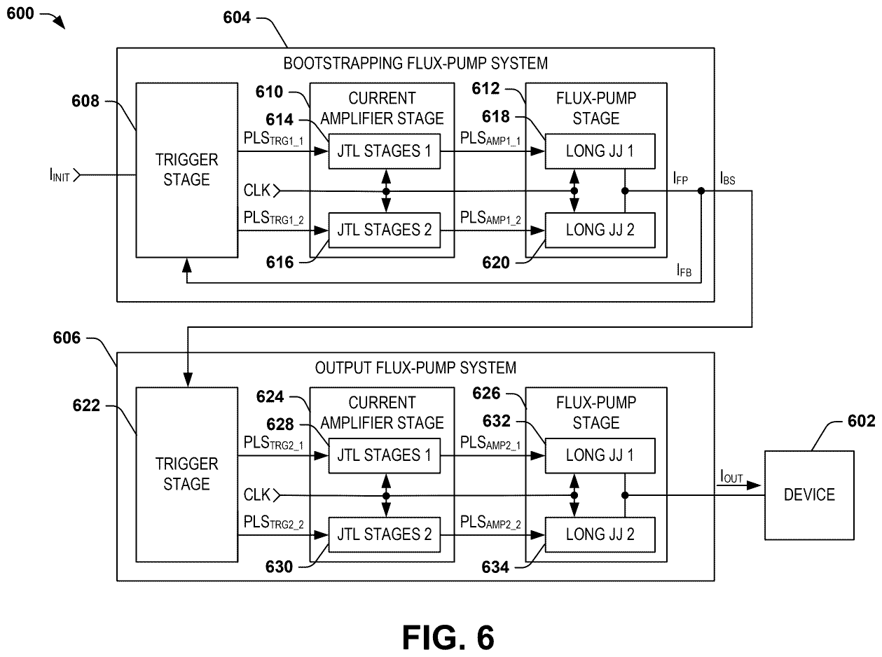

FIG. 6 illustrates another example circuit diagram of a superconducting circuit system 600. As an example, the superconducting circuit system 600 can be implemented in any of a variety of superconductor computing applications. The superconducting circuit system 600 includes a device 602 that receives a DC output current, demonstrated in the example of FIG. 6 as a DC output current I_{OUT}. As an example, the device 602 can correspond to a memory driver, such as to provide a read current or a write current to a memory cell. For example, the device 602 may require greater operational margins with respect to voltage and/or current, such as to necessitate higher voltage and/or current amplitudes.

The superconducting circuit system 600 also includes a bootstrapping flux-pump system 604 that is arranged as a first linear flux-pump system and an output flux-pump system 606 that is arranged as a second linear flux-pump system. The bootstrapping flux-pump system 604 and the output flux-pump system 606 are arranged in a cascaded sequence with respect to each other. In the example of FIG. 6, the bootstrapping flux-pump system 604 provides a DC bootstrapping current I_{BS} at an output, with the bootstrapping current I_{BS} being provided as an input to the output flux-pump system 606. The output flux-pump system 606 thus generates the DC output current I_{OUT} to the device 102.

In the example of FIG. 6, the bootstrapping flux-pump system 604 includes a trigger stage 608, a current amplifier stage 610, and a flux-pump stage 612. As an example, the trigger stage 608 can be configured to generate a pair of pulse trains PLS_{TRG1_1} and PLS_{TRG1_2} in response to an initialization current I_{INIT}. The trigger stage 608 can be configured similar to the trigger stage 200 in the example of FIG. 2. Therefore, the pulse trains PLS_{TRG1_1} and PLS_{TRG1_2} can be generated by a Josephson junction that is triggered by the initialization current I_{INIT}, and can receive a feedback current I_{FB} to sustain the operation of the bootstrapping flux-pump system 604 after the initialization current I_{INIT} ceases to the bootstrapping flux-pump system 604.

In the example of FIG. 6, the current amplifier stage 610 includes a first set of JTL stages 614 and a second set of JTL stages 616 that each include a sequential arrangement of JTL stages. As an example, the current amplifier stage 610 can be arranged substantially similar to the current amplifier stage 300 in the example FIG. 3, such that the sets of JTL stages 614 and 616 can be arranged substantially the same as the respective JTL stages 302 and 304. Therefore, the Josephson junctions of each JTL stage of the first set of JTL stages 614 triggers in response to the first phase of the clock signal CLK and the first pulse train PLS_{TRG1_1} to propagate pulses along the set of JTL stages 614 to generate a first MFQ pulse PLS_{AMP1_1}. Similarly, the Josephson junctions of each JTL stage of the second set of JTL stages 616 triggers in response to the second phase of the clock signal CLK and the second pulse train PLS_{TRG1_2} to propagate pulses along the set of JTL stages 616 to generate a second MFQ pulse PLS_{AMP1_2}.

Also in the example of FIG. 6, the flux-pump stage 612 includes a first long Josephson junction 618 and a second long Josephson junction 620. The flux-pump stage 612 can be arranged substantially similar to the flux-pump stage 500 in the example of FIG. 5, such that the long Josephson junctions 618 and 620 can correspond to the long Josephson junctions 502 and 504, respectively. Therefore, the first long Josephson junction 618 is configured to trigger in response to the first MFQ pulse PLS_{AMP1_1} provided from the first set of JTL stages 614 of the current amplifier stage 610 and the first phase of the clock signal CLK to generate a first long Josephson junction pulse. Similarly, the second long Josephson junction 620 is configured to trigger in response to the second MFQ pulse PLS_{AMP1_2} provided from the second set of JTL stages 616 of the current amplifier stage 610 and the second phase of the clock signal CLK to generate a second long Josephson junction pulse. The long Josephson junction pulses collectively form a flux-pump current I_{FP}. The flux-pump current I_{FP} is demonstrated as split into the feedback current I_{FB}, which is provided back to the trigger stage 608 to sustain operation of the bootstrapping flux-pump system 604, and the bootstrapping current I_{BS}.

In the example of FIG. 6, the output flux-pump system 606 includes a trigger stage 622, a current amplifier stage 624, and a flux-pump stage 626. As an example, the trigger stage 622 can be configured to generate a pair of pulse trains PLS_{TRG2_1} and PLS_{TRG2_2} in response to the bootstrapping current I_{BS}. The trigger stage 622 can be configured similar to the trigger stage 200 in the example of FIG. 2. However, the trigger stage 622 may not be initialized by an inductively-coupled initialization current I_{INIT}. Instead, the bootstrapping current I_{BS} can replace both the initialization current I_{INIT} and the feedback current I_{FB}, such that the bootstrapping current I_{BS} can be provided to continuously trigger the Josephson junction of the trigger stage 622 to generate the pulse trains PLS_{TRG2_1} and PLS_{TRG2_2}.

In the example of FIG. 6, the current amplifier stage 624 includes a first set of JTL stages 628 and a second set of JTL stages 630 that each include a sequential arrangement of JTL stages. As an example, the current amplifier stage 624 can be arranged substantially similar to the current amplifier stage 300 in the example FIG. 3, such that the sets of JTL stages 628 and 630 can be arranged substantially the same as the respective JTL stages 302 and 304. Therefore, the Josephson junctions of each JTL stage of the first set of JTL stages 628 triggers in response to the first phase of the clock signal CLK and the first pulse train PLS_{TRG2_1} to propagate pulses along the set of JTL stages 628 to generate a first MFQ pulse PLS_{AMP2_1}. Similarly, the Josephson junctions of each JTL stage of the second set of JTL stages 630 triggers in response to the second phase of the clock signal CLK and the second pulse train PLS_{TRG2_2} to propagate pulses along the set of JTL stages 630 to generate a second MFQ pulse PLS_{AMP2_2}.

Also in the example of FIG. 6, the flux-pump stage 626 includes a first long Josephson junction 632 and a second long Josephson junction 634. The flux-pump stage 626 can be arranged substantially similar to the flux-pump stage 500 in the example of FIG. 5, such that the long Josephson junctions 632 and 634 can correspond to the long Josephson junctions 502 and 504, respectively. Therefore, the first long Josephson junction 632 is configured to trigger in response to the first MFQ pulse PLS_{AMP2_1} provided from the first set of JTL stages 628 of the current amplifier stage 624 and the first phase of the clock signal CLK to generate a first long Josephson junction pulse. Similarly, the second long Josephson junction 634 is configured to trigger in response to the second MFQ pulse PLS_{AMP2_2} provided from the second set of JTL stages 630 of the current amplifier stage 624 and the second phase of the clock signal CLK to generate a second long Josephson junction pulse. The long Josephson junction pulses collectively form the DC output current I_{OUT} that is provided to the device 602.

In this manner, the cascaded bootstrapping flux-pump system 604 and output flux-pump system 606 can provide for a greater amplitude of the DC output current I_{OUT} and/or the associated output voltage. While the example of FIG. 6 demonstrates two stages of linear flux-pump systems, additional stages can be implemented to provide an associated DC output current I_{OUT}.

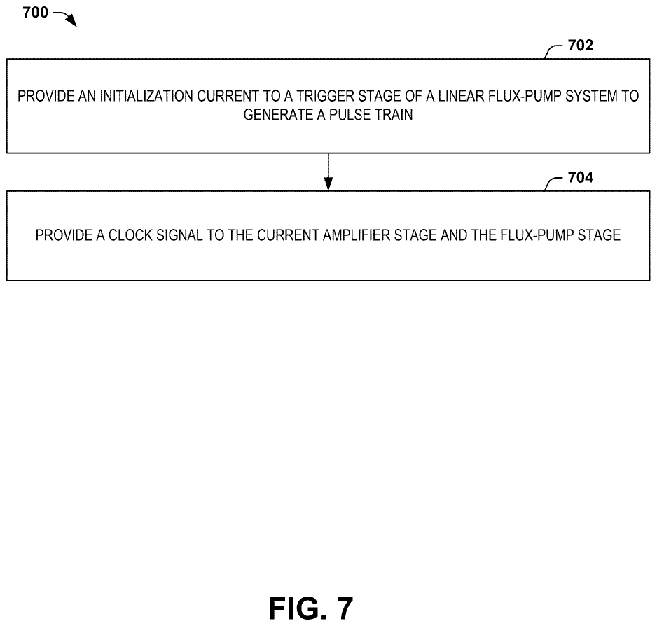

In view of the foregoing structural and functional features described above, a methodology in accordance with various aspects of the present invention will be better appreciated with reference to FIG. 7. While, for purposes of simplicity of explanation, the methodology of FIG. 7 is shown and described as executing serially, it is to be understood and appreciated that the present invention is not limited by the illustrated order, as some aspects could, in accordance with the present invention, occur in different orders and/or concurrently with other aspects from that shown and described herein. Moreover, not all illustrated features may be required to implement a methodology in accordance with an aspect of the present invention.

FIG. 7 illustrates an example of a method 700 for generating a DC output current (e.g., the DC output current I_{OUT}). At 702, an initialization current (e.g., the initialization current I_{INIT}) is provided to a trigger stage (e.g., the trigger stage 106) of a linear flux-pump system (e.g., the linear flux-pump system 104) to generate a pulse train (e.g., the pulse train PLS_{TRG}). The linear flux-pump system further includes a current amplifier stage (e.g., the current amplifier stage 108) and a flux-pump stage (e.g., the flux-pump stage 110). At 704, a clock signal (e.g., the clock signal CLK) is provided to the current amplifier stage and the flux-pump stage. The current amplifier stage can be configured to generate MFQ pulses (e.g., the MFQ pulse PLS_{AMP}) via JTL stages (e.g., the JTL stages 112) in response to the pulse train and the clock signal, and the flux-pump stage can be configured to generate the DC output current in response to the MFQ pulses and the clock signal.

What have been described above are examples of the invention. It is, of course, not possible to describe every conceivable combination of components or methodologies for purposes of describing the invention, but one of ordinary skill in the art will recognize that many further combinations and permutations of the invention are possible. Accordingly, the invention is intended to embrace all such alterations, modifications, and variations that fall within the scope of this application, including the appended claims. Additionally, where the disclosure or claims recite “a,” “an,” “a first,” or “another” element, or the equivalent thereof, it should be interpreted to include one or more than one such element, neither requiring nor excluding two or more such elements. As used herein, the term “includes” means includes but not limited to, and the term “including” means including but not limited to. The term “based on” means based at least in part on.

What is claimed is:

1. A linear flux-pump system comprising:
a trigger stage configured to generate a pulse train in response to an initialization current;
a current amplifier stage comprising a plurality of Josephson transmission line (JTL) stages configured to propagate multiple flux quanta (MFQ) pulses based on a clock signal in response to the pulse train; and
a flux-pump stage configured to aggregate the MFQ pulses based on the clock signal to generate a DC output current.

2. The system of claim 1, wherein the flux-pump stage is configured to aggregate the MFQ pulses based on the clock signal to generate a feedback current and the DC output current, wherein the trigger stage comprises a trigger Josephson junction configured to generate the pulse train in response to the initialization current provided as a current pulse, and to thereafter trigger in response to the feedback current.

3. The system of claim 1, wherein the JTL stages are arranged in a sequence from an input coupled to the trigger stage to receive the pulse train to an output coupled to the flux-pump stage to which the MFQ pulses are provided, wherein each of the JTL stages of the current amplifier stage comprises at least one Josephson junction configured to trigger in the sequence in response to the clock signal to generate the MFQ pulses.

4. The system of claim 3, wherein the at least one Josephson junction of each of the JTL stages is progressively greater in size in the sequence of the JTL stages between the input and the output.

5. The system of claim 3, wherein the at least one Josephson junction of each of the JTL stages is shunted.

6. The system of claim 1, wherein the clock signal is provided to each of the JTL stages of the current amplifier stage via a coupling transformer, wherein the coupling transformer exhibits a mutual inductance that induces at least 2Φ₀ flux in the secondary winding.

7. The system of claim 1, wherein the flux-pump stage comprises a long Josephson junction comprising a plurality of unshunted Josephson junctions and a respective plurality of inductors that are interleaved with each other, the long Josephson junction being inductively coupled to the clock signal to collectively trigger the unshunted Josephson junctions of the long Josephson junction in response to one of the MFQ pulses to generate a current pulse corresponding to the DC output current at an output of the flux-pump stage.

8. The system of claim 1, wherein the trigger stage is a first trigger stage configured to generate a first pulse train, wherein the current amplifier stage is a first current amplifier stage comprising a first plurality of JTL stages configured to propagate first MFQ pulses in response to the first pulse train, wherein the flux-pump stage is a first flux-pump stage configured to aggregate the first MFQ pulses to generate a first DC output current, wherein the first trigger stage, the first current amplifier stage, and the first flux-pump stage collectively form a bootstrapping flux-pump system, the system further comprising an output flux-pump system, the output flux-pump system comprising:
a second trigger stage configured to generate a second pulse train in response to the first DC output current;
a second current amplifier stage comprising a second plurality of JTL stages configured to propagate second MFQ pulses in a sequence based on the clock signal in response to the second pulse train; and
a second flux-pump stage configured to aggregate the second MFQ pulses based on the clock signal to generate a second DC output current.

9. The system of claim 1, wherein the JTL stages of the current amplifier stage is a first plurality of JTL stages configured to propagate first MFQ pulses in response to the pulse train and a first phase of the clock signal, wherein the current amplifier stage further comprises a second plurality of JTL stages configured to propagate second MFQ pulses in response to the pulse train and a second phase of the clock signal, the second phase being opposite the first phase, wherein the flux-pump stage comprises:
a first long Josephson junction comprising a first plurality of Josephson junctions inductively coupled to the clock signal to trigger in response to the first MFQ pulses and the first phase of the clock signal to generate a first portion of the DC output current; and
a second long Josephson junction comprising a second plurality of Josephson junctions inductively coupled to the clock signal to trigger in response to the second MFQ pulses and the second phase of the clock signal to generate a second portion of the DC output current.

10. The system of claim 9, wherein the clock signal is inductively provided as a bias current to one of each of the first and second JTL stages of the current amplifier stage via a secondary of a coupling transformer, such that a bias input to one of the first JTL stages and a bias input to one of the second JTL stages are electrically coupled via the secondary of the coupling transformer, such that the bias current is provided through the secondary of the coupling transformer in a first polarity at the first phase of the clock signal and in a second polarity at the second phase of the clock signal.

11. A method for generating a DC output current, the method comprising:
providing an initialization current to a trigger stage of a linear flux-pump system to generate a pulse train, the linear flux-pump system further comprising a current amplifier stage and a flux-pump stage; and
providing a clock signal to the current amplifier stage and the flux-pump stage, the current amplifier stage being configured to generate multiple flux quanta (MFQ) pulses via Josephson transmission line (JTL) stages in response to the pulse train and the clock signal, and the flux-pump stage being configured to generate the DC output current in response to the MFQ pulses and the clock signal.

12. The method of claim 11, wherein providing the clock signal comprises generating a feedback current and the DC output current via the flux-pump stage in response to the MFQ pulses and the clock signal, wherein the trigger stage comprises a trigger Josephson junction, wherein providing the initialization current comprises providing the initialization current to the trigger stage to generate the pulse train in response to the initialization current, the method further comprising providing the feedback current to the trigger stage to trigger the trigger Josephson junction to generate the pulse train, wherein ceasing the initialization current comprises ceasing the initialization current after the feedback current is provided to the trigger stage.

13. The method of claim 11, wherein providing the clock signal comprises inductively providing the clock signal via coupling transformers to each of the JTL stages arranged in a sequence from an input coupled to the trigger stage to receive the pulse train to an output coupled to the flux-pump stage to which the MFQ pulses are provided, wherein each of the coupling transformers exhibit a mutual inductance that induces at least 2Φ₀ flux in the secondary winding., wherein each of the JTL stages of the current amplifier stage comprises at least one shunted Josephson junction that is progressively greater in size in the sequence of the JTL stages between the input and the output and are configured to trigger in the sequence in response to the clock signal to generate the MFQ pulses.

14. The method of claim 11, wherein providing the clock signal comprises providing the clock signal to a long Josephson junction of the flux-pump stage, the long Josephson junction comprising a plurality of unshunted Josephson junctions that collectively provide a current pulse corresponding to the DC output current in response to being triggered by the clock signal and one of the MFQ pulses.

15. The method of claim 11, wherein the JTL stages of the current amplifier stage is a first plurality of JTL stages, wherein providing the clock signal comprises:
providing the clock signal to the first JTL stages to propagate first MFQ pulses in response to the pulse train and a first phase of the clock signal, and to a second plurality of JTL stages of the current amplifier stage to propagate second MFQ pulses in response to the pulse train and a second phase of the clock signal, the second phase being opposite the first phase; and
providing the clock signal to a first long Josephson junction and a second long Josephson junction of the flux-pump stage, the first long Josephson junction comprising a first plurality of Josephson junctions inductively coupled to the clock signal to trigger in response to the first MFQ pulses and the first phase of the clock signal to generate a first portion of the DC output current, the second long Josephson junction comprising a second plurality of Josephson junctions inductively coupled to the clock signal to trigger in response to the second MFQ pulses and the second phase of the clock signal to generate a second portion of the DC output current.

16. A linear flux-pump system comprising:
a trigger stage configured to generate a pulse train in response to an initialization current;
a current amplifier stage comprising:
a first plurality of Josephson transmission line (JTL) stages configured to propagate first multiple flux quanta (MFQ) pulses based on a first phase of a clock signal in response to the pulse train; and
a second plurality of JTL stages configured to propagate second MFQ pulses based on a second phase of the clock signal in response to the pulse train, the second phase being opposite the first phase; and
a flux-pump stage comprising:
a first long Josephson junction comprising a first plurality of Josephson junctions inductively coupled to the clock signal to trigger in response to the first MFQ pulses and the first phase of the clock signal to generate a first portion of a DC output current; and
a second long Josephson junction comprising a second plurality of Josephson junctions inductively coupled to the clock signal to trigger in response to the second MFQ pulses and the second phase of the clock signal to generate a second portion of the DC output current.

17. The system of claim 16, wherein the flux-pump stage is configured to aggregate the first and second MFQ pulses in each period of the clock signal to generate a feedback current and the DC output current, wherein the trigger stage comprises a trigger Josephson junction configured to generate the pulse train in response to the initialization current provided as a current pulse, and to thereafter trigger in response to the feedback current.

18. The system of claim 16, wherein the first and second JTL stages are arranged in a sequence from an input coupled to the trigger stage to receive the pulse train to an output coupled to the flux-pump stage to which the MFQ pulses are provided, wherein each of the first and second JTL stages of the current amplifier stage comprises at least one shunted Josephson junction configured to trigger in the sequence in response to the clock signal to generate the MFQ pulses.

19. The system of claim 18, wherein the clock signal is provided to each of the first and second JTL stages via respective coupling transformers, wherein each of the coupling transformers exhibit a mutual inductance that induces at least 2Φ₀ flux in the secondary winding.

20. The system of claim 16, wherein the trigger stage is a first trigger stage configured to generate a first pulse train, wherein the current amplifier stage is a first current amplifier stage, wherein the flux-pump stage is a first flux-pump stage configured to generate a first DC output current, wherein the first trigger stage, the first current amplifier stage, and the first flux-pump stage collectively forming a bootstrapping flux-pump system, the system further comprising an output flux-pump system, the output flux-pump system comprising:
a second trigger stage configured to generate a second pulse train in response to the first DC output current;
a second current amplifier stage comprising:
a third plurality of JTL stages configured to propagate third MFQ pulses based on the first phase of a clock signal in response to the second pulse train; and
a fourth plurality of JTL stages configured to propagate fourth MFQ pulses based on the second phase of the clock signal in response to the second pulse train; and
a second flux-pump stage comprising:
a third long Josephson junction comprising a third plurality of Josephson junctions inductively coupled to the clock signal to trigger in response to the third MFQ pulses and the first phase of the clock signal to generate a first portion of a second DC output current; and
a fourth long Josephson junction comprising a fourth plurality of Josephson junctions inductively coupled to the clock signal to trigger in response to the fourth MFQ pulses and the second phase of the clock signal to generate a second portion of the second DC output current.
